(19) United States
(12) Patent Application Publication
(10) Pub. No.: US 2024/0096854 A1
(43) Pub. Date: Mar. 21, 2024

(54) PIXEL ISOLATION STRUCTURES AND METHODS OF MAKING THEM

(71) Applicant: Applied Materials, Inc., Santa Clara, CA (US)

(72) Inventors: Zhiyong Li, Foster City, CA (US); Sivapackia Ganapathiappan, Los Altos, CA (US); Kulandaivelu Sivanandan, Fremont, CA (US); Hao Yu, Los Angeles, CA (US); Hou T. Ng, Campbell, CA (US); Nag Patibandla, Pleasanton, CA (US); Mingwei Zhu, San Jose, CA (US); Lisong Xu, San Jose, CA (US); Kai Ding, Fremont, CA (US)

(73) Assignee: Applied Materials, Inc., Santa Clara, CA (US)

(21) Appl. No.: 18/244,466

(22) Filed: Sep. 11, 2023

Related U.S. Application Data
(60) Provisional application No. 63/406,929, filed on Sep. 15, 2022.

(51) Int. Cl. H01L 25/075

(52) U.S. Cl. CPC H01L 25/0753; H01L 33/56

(57) ABSTRACT

Processing methods are described that include forming a group of LED structures on a substrate layer to form a patterned LED substrate. The methods also include depositing a light absorption material on the pattered LED substrate, where the light absorption material includes at least one photocurable compound and at least one ultraviolet light absorbing material. The methods further include exposing a portion of the light absorption material to patterned light, wherein the patterned light cures the exposed portion of the light absorption material into pixel isolation structures. The methods additionally include depositing an isotropic layer on a top portion and a side portion of the pixel isolation structures, where the LED structures are substantially free of the as-deposited isotropic light reflecting layer.

### CROSS-REFERENCE TO RELATED APPLICATIONS

This application claims the benefit of, and priority to U.S. Provisional Application Ser. No. 63/406,929, filed Sep. 15, 2022, which is hereby incorporated by reference in its entirety for all purposes.

### FIELD

The present technology relates to displays having pixels that include pixel isolation structures to prevent crosstalk between adjacent pixels.

### BACKGROUND

High-resolution light-emitting diode (LED) displays can include millions of micron-sized pixels arranged to form a viewing screen. Conventional LED displays generate a color image by filtering down white light from an LED light source into red, green, and blue pixels that emit at varying intensities across the viewing screen. Other LED displays excite organic or inorganic compounds, so they emit light of a particular color, such as red, green, or blue light, depending on the pixel. These LED displays typically require fewer filters to block the light of unwanted colors and can produce a more accurate color gamut. However, they emit and scatter the light in all directions which can create photoluminescent crosstalk between adjacent pixels that distort the color of the displayed images.

Thus, there is a need for pixel designs that generate images with less photoluminescent crosstalk for display devices that include excitable light-emitting materials. These and other needs are addressed by the present technology.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 shows a flowchart with selected operations of an exemplary method of fabricating a pixel structure according to embodiments of the present technology.

FIGS. 2A-E show simplified cross-sectional views of fabrication stages for an exemplary single pixel structure according to embodiments of the present technology.

FIG. 3 shows another flowchart with selected operations of an exemplary method of fabricating a pixel structure according to embodiments of the present technology.

FIGS. 4A-D show additional simplified cross-sectional views of fabrication stages for an exemplary single pixel structure according to embodiments of the present technology.

### BRIEF SUMMARY

Embodiments of the present technology include processing methods that include forming a group of LED structures on a substrate layer to form a patterned LED substrate. The methods also include depositing a light absorption material on the pattered LED substrate, where the light absorption material includes at least one photocurable compound and at least one ultraviolet light absorbing material. The methods further include exposing a portion of the light absorption material to patterned light, wherein the patterned light cures the exposed portion of the light absorption material into pixel isolation structures. The methods additionally include depositing an isotropic layer on a top portion and a side portion of the pixel isolation structures, where the LED structures are substantially free of the as-deposited isotropic light reflecting layer.

In additional embodiments, the depositing of the light absorption material on the patterned LED substrate includes spin coating the light absorption material on the patterned LED substrate. In further embodiments, the at least one photocurable compound in the light absorption material includes an epoxy-based photocurable material. In still further embodiments, the at least one ultraviolet light absorbing compound in the light absorption material includes benzotriazole derivatives, 2-[3-(2H-Benzotriazol-2-yl)-4-hydroxyphenyl] derivatives and triazine derivatives. In yet additional embodiments, the methods further include rinsing the uncured light absorption material from the patterned LED substrate after curing the exposed portion of the light absorption material into the pixel isolation structure. In more embodiments, the depositing of the isotropic light reflecting layer includes a directional deposition of the isotropic light reflecting layer on the top and side portions of the pixel isolation structures, and where the directional deposition does not deposit the isotropic light reflecting layer across a top surface of the LED structures. In still more embodiments, the pixel isolation structures form sidewalls of photoluminescent regions positioned on the LED structures of the patterned LED substrate. In yet further embodiments, the pixel isolation structures form sidewalls of the photoluminescent regions positioned on the LED structures of the patterned LED substrate.

Additional embodiments of the present technology include processing methods that include depositing a light absorption material on a substrate, where the light absorption material includes at least one photocurable compound and at least one ultraviolet light absorbing compound. The methods further include exposing a portion of the light absorption material to patterned light, where the patterned light cures the exposed portion of the light absorption material into a first portion of pixel isolation structures, and where the first portion of the pixel isolation structures form sidewalls of photoluminescent regions positioned on the substrate. The methods additionally include depositing an isotropic light reflecting layer on the sidewalls of the first portion of the pixel isolation structures, where the substrate is substantially free of the as-deposited isotropic light reflecting layer.

In further embodiments, the methods include depositing a photoluminescent material in at least a portion of the photoluminescent regions to form a photoluminescent component. In additional embodiments, the methods further include attaching the photoluminescent component to a patterned LED substrate, where the patterned LED substrate includes a second portion of the pixel isolation structures that bond to the first portion of the pixel isolation structures along top sides of the first and second portions of the pixel isolation structures. In yet additional embodiments, the at least one photocurable compound in the light absorption material includes an epoxy-based photocurable material. In still further embodiments, the at least one ultraviolet light absorbing compound in the light absorption material includes benzotriazole derivatives, 2-[3-(2H-Benzotriazol-2-yl)-4-hydroxyphenyl] derivatives and triazine derivatives. In more embodiments, the depositing of the isotropic light reflecting layer includes a directional deposition of the isotropic light reflecting layer on the sidewalls of the first portion of the pixel isolation structures, where the directional deposition does not deposit the isotropic light reflecting layer across the substrate.

Further embodiments of the present technology include display structures that include a light emitting diode structure operable to generate ultraviolet light. The structures further include a photoluminescent region containing a photoluminescent material, and a pixel isolation structure that includes at least one photocurable compound and at least one ultraviolet light absorbing compound, where at least one sidewall of the photoluminescent region includes the pixel isolation structure. The structures also include a light reflecting layer positioned between the photoluminescent material in the photoluminescent region and the pixel isolation structure.

In more embodiments, the light emitting diode structure includes a micro-light-emitting-diode operable to generate ultraviolet light characterized by a wavelength less than or about 420 nm. In still more embodiments, the photoluminescent material in the photoluminescent region includes a quantum dot material operable to absorb the ultraviolet light from the light emitting diode structure and emit visible light characterized by a wavelength of greater than 420 nm. In yet additional embodiments, the at least one photocurable compound in the light absorption material includes an epoxy-based photocurable material. In still further embodiments, the at least one ultraviolet absorbing compound in the light absorption material includes benzotriazole derivatives, 2-[3-(2H-Benzotriazol-2-yl)-4-hydroxyphenyl] derivatives and triazine derivatives. In still more embodiments, the light reflecting layer includes at least one metal compound selected from the group consisting of aluminum, copper, chromium, silver, gold, platinum, and molybdenum.

The present technology provides several benefits over conventional methods of making pixel structures that include a light emitting diode component and photoluminescent region containing photoluminescent materials. In conventional fabrication methods, patterned LED substrates are covered by a silicon-containing passivation film before undergoing a series of photolithographic patterning operations to form the scaffolding for an anisotropically-deposited reflective light reflecting layer. Both deposition and removal operations for the passivation film, photolithographic resists, and portions of the light reflecting layer are required to form the pixel structure that includes both the light emitting diode component and the photoluminescent region. All these operations significantly reduce the fabrication efficiency of the pixel structures. In contrast, embodiments of the present technology deposit a light absorption material that includes both photocurable and ultraviolet light absorbing compounds that can be cured into a pixel isolation structure. Instead of multiple operations to deposit, pattern, and remove a photocurable material to form the pixel isolation structure, embodiments of the present technology permit a single deposition and patterned curing of the light absorption material to form the pixel isolation structure. The initial light absorption material is wet and may be spin coated on a structured LED substrate and the uncured portion of light absorption material following patterning may be rinsed off in a single operation. Embodiments of the present technology also include a directional deposition of a reflective light reflecting layer that deposits the light reflecting layer on those portions of the pixel isolation structure that increases the percentage of light directed into a displayed image while leaving other portions of the pixel structure uncoated, such as the top surfaces of the light emitting diode structures. This eliminates another removal operation in conventional fabrication processes that open a blanket-deposited light reflecting layer at those LED surfaces to permit the transmission of the LED-generated light into the photoluminescent region of the pixel structure. These and other embodiments, along with many of their advantages and features, are described in more detail in conjunction with the below description and attached figures.

### DETAILED DESCRIPTION

Technological advances in high-resolution displays include the development of micro-light-emitting-diodes (μLEDs) from inorganic semiconductor materials and the use of photoluminescent materials like quantum dots in the displays. μLEDs are made of layers of semiconductor materials, such as indium gallium nitride (InGaN), that can be arranged to emit light of a specific peak emission wavelength when excited by an applied electric field. Semiconductor fabrication processes are used to make μLEDs having a longest dimension of less than or about 50 μm and operable to emit red, green, or blue light. Quantum dots are nanometer-sized particles of inorganic materials that can emit light of a particular color after being excited by more energetic light. The color of the emitted light may depend on one or more characteristics of the particles, including their size, shape, and composition, among other characteristics. For quantum dots made of inorganic semiconductor materials, the color of the light they emit depends on an energy gap between the conduction band and the valence band of the dots. When the quantum dots are excited, one or more electrons jump from the lower-energy valence band to the higher-energy conduction band. As the excited electrons fall back down to the valence band, they emit light having a color that depends on the size of the energy gap between the valence band and the conduction band. The narrower the energy gap, the more the emitted light is shifted to the red, while the wider the energy gap, the more the emitted light is shifted to the blue. By adjusting one or more characteristics of the quantum dots that change the energy gap between the conduction and valence bands, quantum dots can be made that emit light of practically any color in the visible spectrum.

Additional advances have combined μLEDs and quantum dots in a high-resolution display. The μLEDs are independently switched on and off by electronic circuitry in a backplane control panel to generate source light that photoexcites the quantum dots. The more energetic μLED source light, such as blue or ultraviolet light, excites the quantum dots and causes them to emit light of a specific, less-energetic, color such as blue, green, orange, or red light. The excited quantum dots can emit light with improved emissions characteristics, such as a narrower band full-width-half-maximum wavelength spectrum, than the μLEDs. The ability of the quantum dots to emit a sharper color of light reduces the number of color filters and polarizers needed in a display to block unwanted colors of light from contaminating the displayed images.

Unfortunately, conventional fabrication methods for making pixel structures that include both μLEDs and photoluminescent regions that include photoluminescent materials have multiple deposition, patterning, and removal operations to form the pixel isolation structures and reflective light reflecting layers along the stack of the μLED and photoluminescent region. These conventional fabrication methods can include covering the LED structures with a silicon-containing passivation film, such as silicon nitride, to protect the LED structures during the formation of the pixel isolation structures. Conventional fabrication methods can also include a series of photolithographic patterning operations to form the scaffolding for an anisotropically-deposited reflective light reflecting layer. Both deposition and removal operations for the passivation film, photolithographic resists, and portions of the light reflecting layer are required to form the pixel structure that includes both the light emitting diode component and the photoluminescent region. All these operations significantly reduce the fabrication efficiency of the pixel structures.

The present technology addresses these and other problems with fabrication methods for making pixel structures by forming the pixel isolation structures and reflective light reflecting layer with significantly fewer operations. In embodiments, the present fabrication methods deposit a light absorption material that includes both photocurable and ultraviolet light absorbing compounds that can be cured into a pixel isolation structure. Instead of multiple operations to deposit, pattern, and remove a photocurable material to form the pixel isolation structure, embodiments of the present technology permit a single deposition and patterned curing of the light absorption material to form the pixel isolation structure. In additional embodiments, the initial light absorption material is wet and may be spin coated on a structured LED substrate and the uncured portion of light absorption material following patterning may be rinsed off in a single operation. In further embodiments, a directional deposition of a reflective light reflecting layer may be performed that deposits the light reflecting layer on those portions of the pixel isolation structure that increases the percentage of light directed into a displayed image while leaving other portions of the pixel structure uncoated, such as the top surfaces of the light emitting diode structures. This eliminates another removal operation in conventional fabrication processes that open a blanket-deposited light reflecting layer at those LED surfaces to permit the transmission of the LED-generated light into the photoluminescent region of the pixel structure.

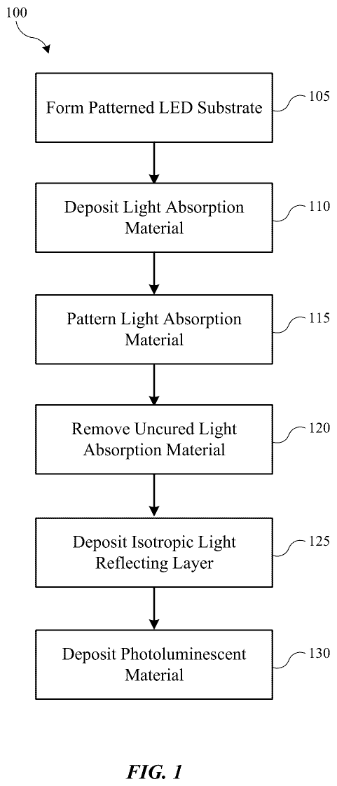

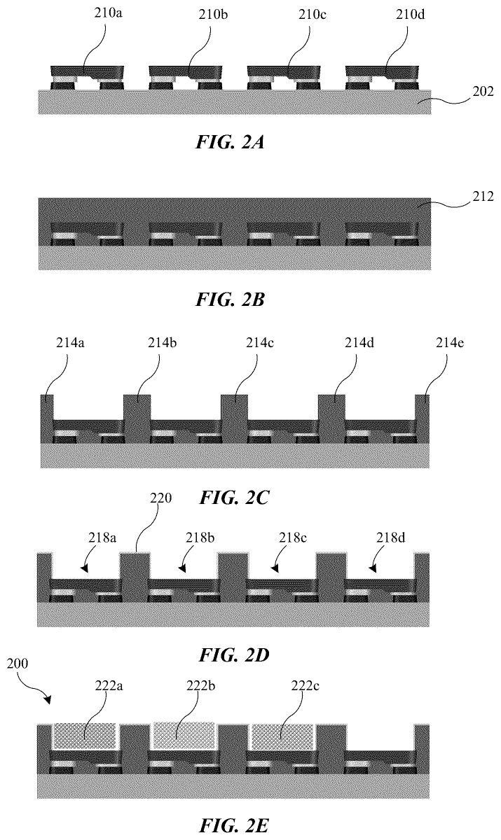

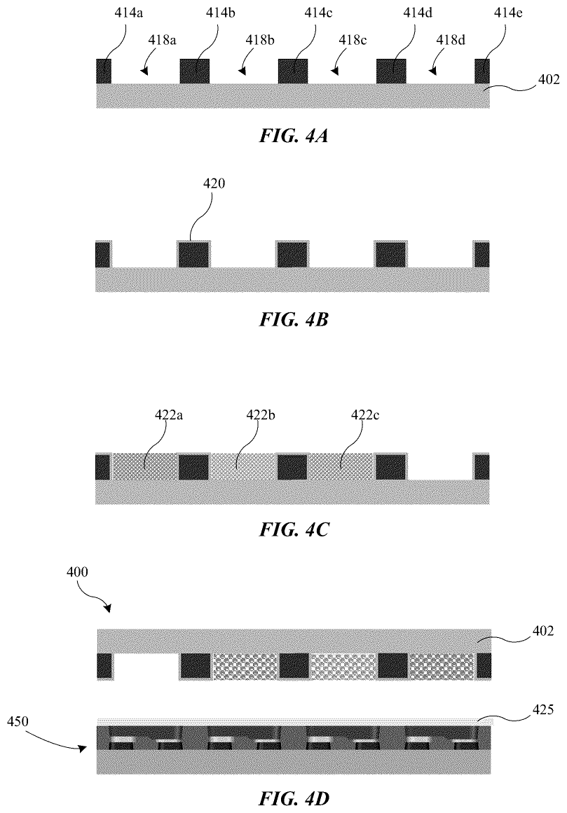

FIG. 1 shows a flowchart with selected operations in method 100 of fabricating a pixel structure 200 according to embodiments of the present technology. Method 100 may or may not include one or more operations prior to the initiation of the method, including front-end processing, deposition, etching, polishing, cleaning, or any other operations that may be performed prior to the described operations. The method may include optional operations, which may or may not be specifically associated with some embodiments of methods according to the present technology. Method 100 describes operations to form embodiments of pixel structures, one of which is shown in a simplified schematic form as pixel structure 200 in FIG. 2E and another of which is shown as pixel structure 400 in FIG. 4D. The cross-sectional view of pixel structures 200 and 400 in FIGS. 2E and 4D is a split-open cross-sectional view that shows the pixel structure that is cut between a first and second pair of subpixels and split open to reveal a cross-sectional liner arrangement of red, green, blue, and blank pixels. FIGS. 2E and 4D illustrate only partial schematic views with limited details. In further embodiments that are not illustrated, exemplary pixel structures may contain additional layers, regions, and materials, having aspects as illustrated in the figures, as well as alternative structural and material aspects that may still benefit from any of the aspects of the present technology.

Method 100 includes forming patterned LED structures 210a-d on a substrate 202 at operation 105, as shown in FIG. 2A. In embodiments, the LED structures 210a-d may be a μLED structures operable to emit blue light or ultraviolet light. In some embodiments the substrate 202 may be removed to expose a surface upon which a photoluminescent region is formed and the LED structures 210a-d. In additional embodiments the substrate 202 may form a backplane in electronic communication with the LED structures 210a-d. In further embodiments, the LED structures 210a-d may be operable to emit ultraviolet light or blue light. In still further embodiments, the LED structures 210a-d may be operable to emit light characterized by a peak emission wavelength of less than or about 400 nm, less than or about 390 nm, less than or about 380 nm, less than or about 370 nm, less than or about 360 nm, less than or about 350 nm, less than or about 340 nm, less than or about 330 nm, or less. In additional embodiments, the LED structures 210a-d may be characterized by a width of less than or about 10 μm, less than or about 5 μm, less than or about 4 μm, less than or about 3.5 μm, less than or about 3 μm, less than or about 2.5 μm, less than or about 2 μm, less than or about 1.5 μm, less than or about 1 μm, or less.

In embodiments, the LED structures 210a-d may be gallium-and-nitrogen-containing LED structures. In further embodiments, the LED structures 210a-d may be gallium nitride LED structures that are epitaxially formed on a substrate or a previously formed LED structure. In additional embodiments, the substrate 202 may be a silicon substrate or a sapphire substrate, among other kinds of substrates. In still additional embodiments, the LED structures 210a-d may further include an n-doped GaN layer and a p-doped GaN layer. Formed between the n-doped and p-doped GaN layers is a multiple-quantum-well (MQW) region where the light emitted by the LED structures 210a-d is generated. The LED structures 210a-d may further include an electrically conductive N-pad contact that forms a pathway for electrical current to pass through the n-doped GaN layer. The LED structures 210a-d may also include an electrically conductive P-pad contact that forms a pathway for electrical current to pass through the p-doped GaN layer. The N-pad and P-pad contacts may be connected to electrically conducive layers in an LED subpixel or directly connected to contacts in the control circuitry of a backplane. In embodiments, electrical signals from the control circuitry create a flow of electrical current through the LED structures 210a-d that cause light emission from the MQW regions of the structures. In additional embodiments, the MQW region is formed to emit light characterized by a repeatable peak intensity wavelength and quantum efficiency for an applied electrical signal (e.g., electrical current and/or voltage). In embodiments, the peak intensity wavelength of the light emitted from the MQW region may be an ultraviolet light wavelength (e.g., a wavelength of light less than or about 400 nm).

Method 100 may further include depositing a light absorption material 212 on the substrate 202 and patterned LED structures 210a-d, as shown in FIG. 2B. In embodiments, the light absorption material 212 may be applied as a liquid or wet slurry to the substrate 202 and patterned LED structures 210a-d. In further embodiments, the light absorption material 212 may be applied using one or more deposition techniques such as spin-on coating, dip coating, spray-on coating, blade coating, and inkjet coating, among other deposition techniques.

In embodiments, the light absorption material 212 includes at least one photoresist compound and at least one ultraviolet light absorbing compound. In additional embodiments, the photoresist compound may include one or more compounds such as diazonaphthoquinone, bis-benzophenone type photoinitiators, bis(aryl azide)-based crosslinkers, a phenol formaldehyde resin, poly(methyl methacrylate), poly(methyl glutarimide), and different types of SU-8, mixture of acrylic monomers thiol-ene resins, polysiloxanes, polyvinylcinnamate among other photoresist compounds.

In more embodiments, the ultraviolet light absorbing compound in the light absorption material 212 may include one or more compounds such as N,N′-Bis(3-methylphenyl)-N,N′-diphenylbenzidine (TPD); N,N′-bis(1-naphthyl)-N,N′-diphenyl-(1,1′-biphenyl)-4,4′-diamine (NPB); N,N′-Bis(phenanthren-9-yl)-N,N′-bis(phenyl)-benzidine (PAPB or PPD); 4,7-Diphenyl-1,10-phenanthroline (BPhen); Bis(8-hydroxy-2-methylquinoline)-(4-phenylphenoxy)aluminum, (BAlq); Tris-(8-hydroxyquinoline)aluminum, (Alq); Tetracene (C₈H₁₂); 4-phenyl (4P); and 6-phenyl (6P); Tinuvin CarboPreotect available from BASF, UV Absorbers Riasorb series from Rianlon; titanium oxide; zinc oxide; and carbon black; among other ultraviolet light absorbing compounds.

In still more embodiments, the light absorption material 212 may include a solvent for the photoresist compounds and/or the ultraviolet light absorbing compounds. In further embodiments, the solvent may include 7-butyrolactone (GBL) and/or cyclopentanone, cyclohexanone, propyl methyl ether acetate, methoxy propyl ether acetate, anisole, toluene, xylenes, dimethyl formamide, acetone, acetyl acetone, methyl ethyl ketone, methyl isobutyl ketone, among other solvents.

Method 100 may also include patterning the light absorption material 212 deposited on the substrate 202 and patterned LED structures 210a-d by exposing the material to patterned light at operation 115. In embodiments, light may be passed through a photolithographic mask to form the patterned light that is projected onto the light absorption material 212. In additional embodiments, the patterned light cures the light absorption material 212 that is exposed to the light while leaving the material that is not exposed to the light in an uncured condition. In further embodiments, the patterned light may include ultraviolet light that is sufficiently energetic to cure the photocurable compounds in the light absorption material 212 by, for example, the photochemical crosslinking of the photocurable compounds.

In additional embodiments, the cured portions of the light absorption material 212 may form pixel isolation structures 214a-e made from the at least one cured photocurable compound and at least one ultraviolet light absorbing compound in the light absorption material. As shown in FIG. 2C, the pixel isolation structures 214a-e may be formed between adjacent patterned LED structures 210a-d. In additional embodiments, the pixel isolations structures 214a-e may also be formed in the interstitial space between the patterned LED structures 210a-d and the substrate 202. In yet further embodiments, the pixel isolation structures 214a-e may be characterized as a light absorption barrier operable to absorb energetic ultraviolet light and wavelengths less than or about 350 nm, less than or about 340 nm, less than or about 330 nm, less than or about 320 nm, less than or about 310 nm, less than or about 300 nm, less than or about 290 nm, less than or about 280 nm, less than or about 270 nm, less than or about 260 nm, less than or about 250 nm, or less. In further embodiments, the pixel isolation structures 214a-e may absorb the energetic ultraviolet light reaching the barrier at greater than or about 50%, greater than or about 60%, greater than or about 70%, greater than or about 80%, greater than or about 90%, greater than or about 92.5%, greater than or about 95%, greater than or about 99%, or more.

Method 100 may also include removing the uncured light absorption material 212 at operation 120. In embodiments, the uncured light absorption material 212 may be removed by a wet rinse operation that washes the uncured material off the substrate 202 and patterned LED structures 210a-d. In additional embodiments, the removal of the uncured light absorption material 212 leaves a top surface of the LED structures 210a-d free of the light absorption material. This permits the LED structures 210a-d to emit light into the photoluminescent regions 218a-d without attenuation from the light absorption material 212 without additional removal operations.

As shown in FIG. 2C, removal of the uncured light absorption material 212 leaves behind the pixel isolation structures 214a-e positioned between adjacent LED structures 210a-d. In further embodiments, the pixel isolation structures extend above the height of the LED structures 210a-d to form part of the sidewall portions of photoluminescent regions 218a-d. In still further embodiments, the pixel isolation structures 214a-e may be characterized by a height of greater than or about 2.5 μm, greater than or about 5 μm, greater than or about 7.5 μm, greater than or about 10 μm, greater than or about 12.5 μm, greater than or about 15 μm, greater than or about 17.5 μm, greater than or about 20 μm, or more. In yet additional embodiments, the pixel isolation structures 214a-e may be characterized by a width of less than or about 5 μm, less than or about 4.5 μm, less than or about 4 μm, less than or about 3.5 μm, less than or about 3 μm, less than or about 2.5 μm, less than or about 2 μm, or less. In still further embodiments the pixel isolation structures 214a-e may be characterized by a height-to-width aspect ratio that is greater than or about 1.5:1, greater than or about 2:1, greater than or about 2.5:1, greater than or about 3:1, greater than or about 3.5:1, greater than or about 4:1, greater than or about 4.5:1, greater than or about 5:1, or more.

Method 100 still further includes depositing an isotropic light reflecting layer 220 on portions of the pixel isolation structures 214a-e at operation 125. In the embodiment shown in FIG. 2D, the isotropic light reflecting layer 220 is deposited on top and side surfaces of the pixel isolation structures 214a-e while not being deposited on the top surface of the LED structures 210a-d adjacent to the photoluminescent regions 218a-d. In embodiments, the lack of light reflecting layer on the top surface of the LED structures 210a-d eliminates a patterned etch operation to remove the light reflecting layer from the top surface while keeping the light reflecting layer on surfaces of the pixel isolation structures 214a-e.

In embodiments, the deposition of the isotropic light reflecting layer 220 may include sputtering or otherwise directing the metal onto the pixel isolation structures 214a-e at an angle other that 90° with respect to the substrate 202. In further embodiments, the substrate 202 may be rotating during the deposition of the isotropic light reflecting layer 220 to cover a larger portion of the sidewalls of the pixel isolation structures 214a-e and keep the light reflecting layer from having an uneven thickness in the direction of the non-orthogonal metal deposition. In more embodiments, the metal that forms the light reflecting layer 220 may be selected from the group consisting of aluminum, copper, chromium, silver, gold, platinum, and molybdenum. In still further embodiments, the light reflecting layer 220 is operable to reflect light directly or indirectly in a direction that increases the efficiency of the pixel structure to turn generated light into displayed images. In embodiments, a portion of the light generated by the LED structures 210a-d that is initially directed away from the photoluminescent regions 218a-d may be redirected by the light reflecting layer 220 in the direction of those photoluminescent regions. In additional embodiments, a portion of the light generated by the photoluminescent materials 222a-c in the photoluminescent regions 218a-c that is initially directed away from the displayed image may be redirected by the light reflecting layer 220 in the direction of the displayed image.

In additional embodiments, the light reflecting layer 220 may have a reflection efficiency of greater than or about 50%, greater than or about 60%, greater than or about 70%, greater than or about 80%, greater than or about 90%, greater than or about 95%, greater than or about 99%, or more, for reflecting light in the ultraviolet and visible portions of the electromagnetic spectrum. In more embodiments, the light reflecting layer 220 is operable to direct a greater portion of the light emitted by the LED structures 210a-d and the photoluminescent materials 222a-c in the photoluminescent regions 218a-c into a direction that contributes to the illumination of a device such as a display or other illuminable device component. In still further embodiments, the light reflecting layer 220 increases the intensity of light from a pixel structure that illuminates a device by greater than or about 5%, greater than or about 10%, greater than or about 15%, greater than or about 20%, greater than or about 25%, or more, compared to the same pixel structure that lacks the light reflecting layer.

Method 100 still also includes depositing photoluminescent materials 222a-c into the photoluminescent regions 218a-c at operation 130, as shown in FIG. 2E. In embodiments, the photoluminescent materials 222a-c may include organic light-emitting compounds and/or inorganic light emitting particles, referred to as quantum dots (QDs), that are operable to absorb light emitted from the LED structure 210a-d and emit light with specific color characteristics. In more embodiments, different photoluminescent materials 222a-c may be deposited in each of the photoluminescent regions 218a-c. In still more embodiments, the pixel structure includes a fourth photoluminescent region 218d in which no photoluminescent material is deposited unless one of the other photoluminescent regions 218a-c fail to generate light within the parameters of the expected brightness and color. In this situation, the photoluminescent region 218d is filled with the same type of photoluminescent material as the failed photoluminescent region and is operable to act as a replacement for the failed photoluminescent region.

In further embodiments, the photoluminescent materials 222a-c are deposited into photoluminescent regions 218a-c that are formed in part from the pixel isolation structures 214a-e coated with light reflecting layer 220. In still further embodiments, the pixel isolation structures 2114a-e extend above and around the LED structures 210a-d. In yet further embodiments, the subpixel isolation structures may extend adjacent to and below the contact regions for the LED structures 210a-d and may further extend down to the backplane of the pixel structure. In still further embodiments, the pixel isolation structures 214a-e may have a height of greater than or about 2.5 μm, greater than or about 5 μm, greater than or about 7.5 μm, greater than or about 10 μm, greater than or about 12.5 μm, greater than or about 15 μm, greater than or about 17.5 μm, greater than or about 20 μm, or more. In yet additional embodiments, the pixel isolation structures 214a-e may have a width of less than or about 5 μm, less than or about 4.5 μm, less than or about 4 μm, less than or about 3.5 μm, less than or about 3 μm, less than or about 2.5 μm, less than or about 2 μm, or less. In still further embodiments the pixel isolation structures 214a-e may have a height-to-width aspect ratio that is greater than or about 1.5:1, greater than or about 2:1, greater than or about 2.5:1, greater than or about 3:1, greater than or about 3.5:1, greater than or about 4:1, greater than or about 4.5:1, greater than or about 5:1, or more. In further embodiments, the pixel isolation structures 214a-e reduce the crosstalk generated by light from adjacent and nearby pixel structures. In embodiments, the reduction in the intensity of light from adjacent and nearby pixel structures may be greater than or about 50%, greater than or about 60%, greater than or about 70%, greater than or about 80%, greater than or about 90%, greater than or about 95%, greater than or about 99%, or more.

In embodiments, the pixel isolation structures 214a-e form sidewalls of the photoluminescent regions 218a-d that also include bottom sides adjacent to the top surfaces of the LED structures 210a-d. In further embodiments, the width of bottom side of the photoluminescent regions 218a-d is less than or about 10 μm, less than or about 5 μm, less than or about 4 μm, less than or about 3.5 μm, less than or about 3 μm, less than or about 2.5 μm, less than or about 2 μm, less than or about 1.5 μm, less than or about 1 μm, or less.

In additional embodiments, the as-deposited photoluminescent material may include one or more photoluminescent precursors in a mixture or slurry that includes a photo-curable fluid and one or more photoluminescent particles or compounds. In further embodiments, the one or more photoluminescent compounds may include quantum dot materials that are operable to emit light with specific color characteristics when excited by a source light. In additional embodiments, these quantum-dot materials may include nanoparticles made of one or more kinds of inorganic semiconductor materials such as indium phosphide, zinc selenide, zinc sulfide, silicon, silicates, and graphene, and doped inorganic oxides, among other semiconductor materials. In more embodiments, the photo-curable fluid may include one or more cross-linkable compounds, a photo-initiator, and a color conversion agent. In additional embodiments, the cross-linkable compounds may include monomers that form a polymer when cured. In more embodiments, the monomers may include acrylate monomers, methacrylate monomers, and acrylamide monomers. In yet more embodiments, the cross-linkable compounds may include a negative photocurable material such as SU-8 photocurable. In further embodiments, the photo-initiator may include phosphine oxide compounds and keto compounds, among other kinds of photo-initiator compounds that generate radicals that initiate the curing of unsaturated compounds when excited by ultraviolet light. Commercially available photo-initiator compounds include Irgacure 184, Irgacure 819, Darocur 1173, Darocur 4265, Darocur TPO, Omnicat 250, and Omnicat 550, among other photo-initiators.

When the as-deposited photoluminescent material includes one or more photoluminescent precursors, the precursors may be cured to form a photoluminescent material 220a-c. In embodiments, the curing operation may include exposing the photoluminescent precursor in the photoluminescent region 218a-c to a curing light that coverts the photoluminescent precursor into the photoluminescent material 220a-c. In still further embodiments, the curing light may be characterized by a peak emission wavelength short enough to activate one or more of the photo-curable compounds in the photo-curable fluid of the photoluminescent precursor. In yet more embodiments, the curing light may be characterized by a peak emission wavelength of less than or about 405 nm, less than or about 400 nm, less than or about 395 nm, less than or about 390 nm, less than or about 385 nm, less than or about 380 nm, less than or about 375 nm, less than or about 370 nm, less than or about 365 nm, less than or about 360 nm, less than or about 355 nm, less than or about 350 nm, less than or about 340 nm, less than or about 330 nm, less than or about 320 nm, less than or about 310 nm, less than or about 300 nm, or less. In still further embodiments, the curing light may be supplied by the LED structures 210. In these embodiments, supplying the curing light from the LED structure 210 may permit the self-alignment of the photoluminescent material 218 in the photoluminescent region 214a-e with the LED structures 210a-d. The self-alignment of the photoluminescent material with the LED structure is increasingly beneficial as the size of the subpixels decreases and the pixel density increases.

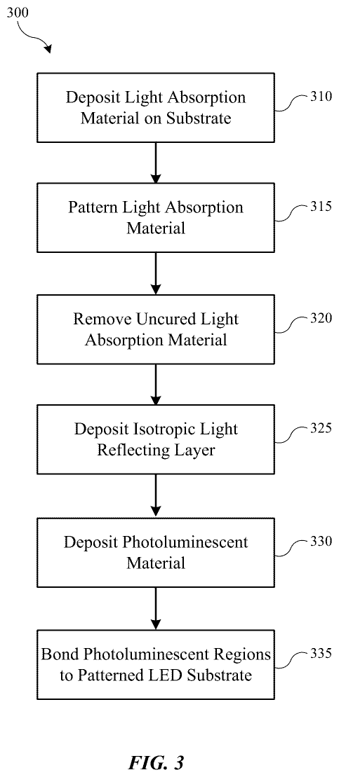

Referring to FIG. 3 and FIGS. 4A-D, another embodiment of a method 300 of fabricating a pixel structure 400 according to embodiments of the present technology is shown. In embodiments, the method 300 includes depositing a light absorption material on a substrate 402 at operation 310. In more embodiments, the substrate 402 may not include patterned LED structures, which will be supplied in a separate component that is attached to the component that includes substrate 302. In additional embodiments, the substrate 402 may be a transparent substrate that is capable of transmitting light generated in the photoluminescent regions 418a-d to a displayed image. In yet additional embodiments, the substrate 402 may be operable to be removed from the photoluminescent regions 418a-d.

In further embodiments, the light absorption material includes at least one photocurable compound and at least one ultraviolent light absorbing material. In additional embodiments, the substrate 402 may include a planar region on which the light absorption material may be deposited as a blanket layer. In still additional embodiments, the light absorption material may be a liquid or slurry, and may be applied using one or more deposition techniques such as spin-on coating, dip coating, spray-on coating, blade coating, and inkjet coating, among other deposition techniques.

Method 300 also includes patterning the deposited light absorption material at operation 315. In embodiments, the patterning operation may include light may be passed through a photolithographic mask to form the patterned light that is projected onto the light absorption material. In additional embodiments, the patterned light cures the light absorption material that is exposed to the light while leaving the material that is not exposed to the light in an uncured condition. In further embodiments, the patterned light may include ultraviolet light that is sufficiently energetic to cure the photocurable compounds in the light absorption material by, for example, the photochemical crosslinking of the photocurable compounds.

Method 300 further includes removing the uncured light absorption material at operation 320. In embodiments, the removal of the uncured light absorption material forms a space for the photoluminescent regions 418a-d, as shown in FIG. 4A. In still further embodiments, the photoluminescent regions 418a-d may include sidewall regions that are formed in part by the pixel isolation structures 414a-e that made during the patterning of the light absorption material deposited on the substrate 402. In yet more embodiments, the photoluminescent regions 418a-d include a top surface that is formed by the surface of the substrate 402 on which the light absorption material is deposited. In embodiments, the substrate 402 may be incorporated into the final pixel structure 400 or may be removed and replaced with different components of the pixel structure.

Method 300 also includes depositing an isotropic light reflecting layer 420 on the pixel isolation structures 414a-e at operation 325, as shown in FIG. 4B. In embodiments, the isotropic light reflecting layer 320 is deposited on top and side surfaces of the pixel isolation structures 414a-e while not being deposited on the surface of the substrate 302 that forms the top surfaces of the photoluminescent regions 418a-d. In embodiments, the lack of light reflecting layer on the surface of substrate 402 eliminates a patterned etch operation to remove the light reflecting layer from the surface while keeping the light reflecting layer on surfaces of the pixel isolation structures 414a-e. In more embodiments, the metal that forms the light reflecting layer 420 may be selected from the group consisting of aluminum, copper, chromium, silver, gold, platinum, and molybdenum. In still further embodiments, the light reflecting layer 320 is operable to reflect light directly or indirectly in a direction that increases the efficiency of the pixel structure to turn generated light into displayed images.

Method 300 still also includes depositing photoluminescent materials 322a-c into the photoluminescent regions 418a-c at operation 330, as shown in FIG. 4C. In embodiments, the photoluminescent materials 422a-c may include organic light-emitting compounds and/or inorganic light emitting particles, referred to as quantum dots (QDs), that are operable to absorb light emitted from the LED structures 410a-d and emit light with specific color characteristics. In more embodiments, different photoluminescent materials 422a-c may be deposited in each of the photoluminescent regions 418a-c. In still more embodiments, the pixel structure includes a fourth photoluminescent region 418d in which no photoluminescent material is deposited unless one of the other photoluminescent regions 418a-c fail to generate light within the parameters of the expected brightness and color. In this situation, the photoluminescent region 418d is filled with the same type of photoluminescent material as the failed photoluminescent region and is operable to act as a replacement for the failed photoluminescent region.

Method 300 may further include bonding the substrate 402 with photoluminescent regions 418a-d to a patterned LED substrate 450 at operation 335, as shown in FIG. 4D. In embodiments, the substrate 402 may be bonded to the patterned LED substrate 450 with a bonding layer 425 that keeps the substrates joined in the final pixel structure 400. In embodiments, the separate fabrication of the photoluminescent regions 418a-d and the patterned LED substrate 450 can accommodate different processing tolerances for the difference substrates, such as different thermal budgets and chemical exposures.

In embodiments of the present technology, the pixel structures 200 and 400 may be incorporated with additional pixel structures to form a display component. In further embodiments, the display component may be incorporated into a display device such as a headset, glasses, a screen, or a monitor, among other display devices. In still further embodiments, the display component containing the present pixel structures may be incorporated into a display device for virtual reality and/or augmented reality service.

In further embodiments, the display component incorporating the present pixel structures may be characterized by a pixel density of greater than or about 500 pixels per inch (ppi), greater than or about 1000 ppi, greater than or about 1500 ppi, greater than or about 2000 ppi, greater than or about 2500 ppi, greater than or about 3000 ppi, greater than or about 3500 ppi, greater than or about 4000 ppi, greater than or about 4500 ppi, greater than or about 5000 ppi, or more. In more embodiments, the increased pixel density of the display component does not result in a decrease brightness of a displayed image generated by the display component. In embodiments, the image brightness may be characterized as greater than or about 100 nits, greater than or about 250 nits, greater than or about 500 nits, greater than or about 750 nits, greater than or about 1000 nits, greater than or about 2500 nits, or more. In still further embodiments, the pixel structures of the present technology may be characterized by an optical density of greater than or about 0.5, greater than or about 0.75, greater than or about 0.8, greater than or about 0.9, greater than or about 0.95, greater than or about 0.99, or more.

Having described several embodiments, it will be recognized by those of skill in the art that various modifications, alternative constructions, and equivalents may be used without departing from the spirit of the invention. Additionally, a number of well-known processes and elements have not been described in order to avoid unnecessarily obscuring the present invention. Accordingly, the above description should not be taken as limiting the scope of the invention.

Where a range of values is provided, it is understood that each intervening value, to the tenth of the unit of the lower limit unless the context clearly dictates otherwise, between the upper and lower limits of that range is also specifically disclosed. Each smaller range between any stated value or intervening value in a stated range and any other stated or intervening value in that stated range is encompassed. The upper and lower limits of these smaller ranges may independently be included or excluded in the range, and each range where either, neither or both limits are included in the smaller ranges is also encompassed within the invention, subject to any specifically excluded limit in the stated range. Where the stated range includes one or both of the limits, ranges excluding either or both of those included limits are also included.

As used herein and in the appended claims, the singular forms “a”, “an”, and “the” include plural referents unless the context clearly dictates otherwise. Thus, for example, reference to “a process” includes a plurality of such processes and reference to “the pixel structure” includes reference to one or more pixel structures and equivalents thereof known to those skilled in the art, and so forth.

Also, the words “comprise,” “comprising,” “include,” “including,” and “includes” when used in this specification and in the following claims are intended to specify the presence of stated features, integers, components, or steps, but they do not preclude the presence or addition of one or more other features, integers, components, steps, acts, or groups.

What is claimed is:

1. A processing method comprising:
forming a group of LED structures on a substrate layer to form a pattered LED substrate;
depositing a light absorption material on the patterned LED substrate, wherein the light absorption material comprises at least one photocurable compound and at least one ultraviolet light absorbing compound;
exposing a portion of the light absorption material to patterned light, wherein the patterned light cures the exposed portion of the light absorption material into pixel isolation structures; and
depositing an isotropic light reflecting layer on a top portion and a side portion of the pixel isolation structures, wherein the LED structures are substantially free of the as-deposited isotropic light reflecting layer.

2. The processing method of claim 1, wherein the depositing of the light absorption material on the patterned LED substrate comprises spin coating the light absorption material on the patterned LED substrate.

3. The processing method of claim 1, wherein the at least one photocurable compound in the light absorption material comprises an epoxy-based photocurable material.

4. The processing method of claim 1, wherein the at least one ultraviolet light absorbing compound in the light absorption material comprises benzotriazole derivatives, 2-[3-(2H-Benzotriazol-2-yl)-4-hydroxyphenyl] derivatives, or triazine derivatives.

5. The processing method of claim 1, wherein the method further comprises rinsing the uncured light absorption material from the patterned LED substrate after curing the exposed portion of the light absorption material into the pixel isolation structures.

6. The processing method of claim 1, wherein the depositing of the isotropic light reflecting layer comprises a directional deposition of the isotropic light reflecting layer on the top and side portions of the pixel isolation structures, and wherein the directional deposition does not deposit the isotropic light reflecting layer across a top surface of the LED structures.

7. The processing method of claim 1, wherein the pixel isolation structures form sidewalls of photoluminescent regions positioned on the LED structures of the patterned LED substrate.

8. The processing method claim 7, wherein the method further comprises depositing a photoluminescent material in the photoluminescent regions.

9. A processing method comprising:
depositing a light absorption material on a substrate, wherein the light absorption material comprises at least one photocurable compound and at least one ultraviolet light absorbing compound;
exposing a portion of the light absorption material to patterned light, wherein the patterned light cures the exposed portion of the light absorption material into a first portion of pixel isolation structures, and wherein the first portion of the pixel isolation structures form sidewalls of photoluminescent regions positioned on the substrate; and
depositing an isotropic light reflecting layer on the sidewalls of the first portion of the pixel isolation structures, wherein the substrate is substantially free of the as-deposited isotropic light reflecting layer.

10. The processing method of claim 9, wherein the method further comprises depositing a photoluminescent material in at least a portion of the photoluminescent regions to form a photoluminescent component.

11. The processing method of claim 9, wherein the method further comprises attaching the photoluminescent component to a patterned LED substrate, wherein the patterned LED substrate comprises a second portion of the pixel isolation structures that bond to the first portion of the pixel isolation structures along top portions of the first and second portions of the pixel isolation structures.

12. The processing method of claim 9, wherein the at least one photocurable compound in the light absorption material comprises an epoxy-based photocurable material.

13. The processing method of claim 9, wherein the at least one ultraviolet light absorbing compound in the light absorption material comprises benzotriazole derivatives, 2-[3-(2H-Benzotriazol-2-yl)-4-hydroxyphenyl] derivatives, or triazine derivatives.

14. The processing method claim 9, wherein the depositing of the isotropic light reflecting layer comprises a directional deposition of the isotropic light reflecting layer on the sidewalls of the first portion of the pixel isolation structures, and wherein the directional deposition does not deposit the isotropic light reflecting layer across the substrate.

15. A display structure comprising:
a light emitting diode structure operable to generate ultraviolet light;
a photoluminescent region containing a photoluminescent material;
a pixel isolation structure comprising at least one photocurable compound and at least one ultraviolet light absorbing compound, wherein at least one sidewall of the photoluminescent region comprises the pixel isolation structure; and
a light reflecting layer positioned between the photoluminescent material in the photoluminescent region and the pixel isolation structure.

16. The display structure of claim 15, wherein the light emitting diode structure comprises a micro light-emitting diode operable to generate ultraviolet light characterized by a wavelength less than or about 420 nm.

17. The display structure of claim 15, wherein the photoluminescent material in the photoluminescent region comprises a quantum dot material operable to absorb the ultraviolet light from the light emitting diode structure and emit visible light characterized by a wavelength greater than 420 nm.

18. The display structure of claim 15, wherein the at least one photocurable compound in the light absorption material comprises an epoxy-based photocurable material.

19. The display structure of claim 15, wherein the at least one ultraviolet light absorbing compound in the light absorption material comprises benzotriazole derivatives, 2-[3-(2H-Benzotriazol-2-yl)-4-hydroxyphenyl] derivatives, or triazine derivatives.

20. The display structure of claim 15, wherein the light reflecting layer comprises at least one metal selected from the group consisting of aluminum, copper, chromium, silver, gold, platinum, and molybdenum.
